(19) United States
(12) Patent Application Publication
(10) Pub. No.: US 2012/0263866 A1
(43) Pub. Date: Oct. 18, 2012

(54) METHOD FOR MEASURING LAYER THICKNESS BY MEANS OF LASER TRIANGULATION, AND DEVICE

(76) Inventors: Torsten Melzer-Jokisch, Neuenhagen bei Berlin (DE); Andreas Oppert, Falkensee (DE); Dimitrios Thomaidis, Berlin (DE)

(21) Appl. No.: 13/502,381

(22) PCT Filed: Jun. 21, 2010
(86) PCT No.: PCT/EP10/58722

§ 371 Date: Jun. 27, 2012

(30) Foreign Application Priority Data
Oct. 19, 2009 (EP) 09013170.7

(51) Int. Cl. C23C 14/54

(52) U.S. Cl. 427/10; 118/712

(57) ABSTRACT

A method for determining the layer thickness of a component to be coated is provided. The monitoring of the process is automated by carrying out laser triangulation measurement before and after the coating of the component. At least one reference point on the component is used to determine the distortion of the blade or vane. A device for carrying out the method is also provided.

### CROSS REFERENCE TO RELATED APPLICATIONS

This application is the US National Stage of International Application No. PCT/EP2010/058722, filed Jun. 21, 2010 and claims the benefit thereof. The International Application claims the benefits of European. Patent Office application No. 09013170.7 EP filed Oct. 19, 2009. All of the applications are incorporated by reference herein in their entirety.

### FIELD OF INVENTION

The invention relates to a method and to a device for measuring layer thickness by means of laser triangulation.

### BACKGROUND OF INVENTION

For quality assessment and for later use, it is important that coated components achieve the required layer thickness at all locations.

This is not possible with the existing measurement methods, e.g. eddy current measurement methods.

Destructive testing precludes the later use of the component and can only be used for parameter optimization.

### SUMMARY OF INVENTION

It is therefore an object of the invention to solve the problem mentioned above.

The object is achieved by a method as claimed in the claims and by a device as claimed in the claims.

### BRIEF DESCRIPTION OF THE DRAWINGS

FIGS. 1, 2 show a schematic sequence of the method according to the invention and of the device,

FIG. 3 is a schematic illustration of the sequence of the method,

FIG. 4 shows positions of the layer thickness measurement,

FIG. 5 shows a gas turbine,

FIG. 6 shows a turbine blade or vane,

FIG. 7 shows a combustion chamber, and

FIG. 8 shows a list of superalloys.

The figures and the description represent only exemplary embodiments of the invention.

### DETAILED DESCRIPTION OF INVENTION

FIG. 1 shows, as a component 1 used by way of example, a turbine blade or vane 120, 130.

The turbine blade or vane 120, 130 can be a new component or a component 120, 130 from which a coating has been removed (from refurbishment) and which was already in use and, for example, has a reduction in wall thickness as a result of the coating removal process.

In a first step, before the coating, the blade or vane 120, 130 is measured by means of a sensor 4 for laser triangulation measurement at each position 13′, 13″ (FIG. 4) at which it appears expedient to check the layer thickness (I in FIG. 3). This can be effected locally at one or more points or can be effected globally over the entire surface to be coated.

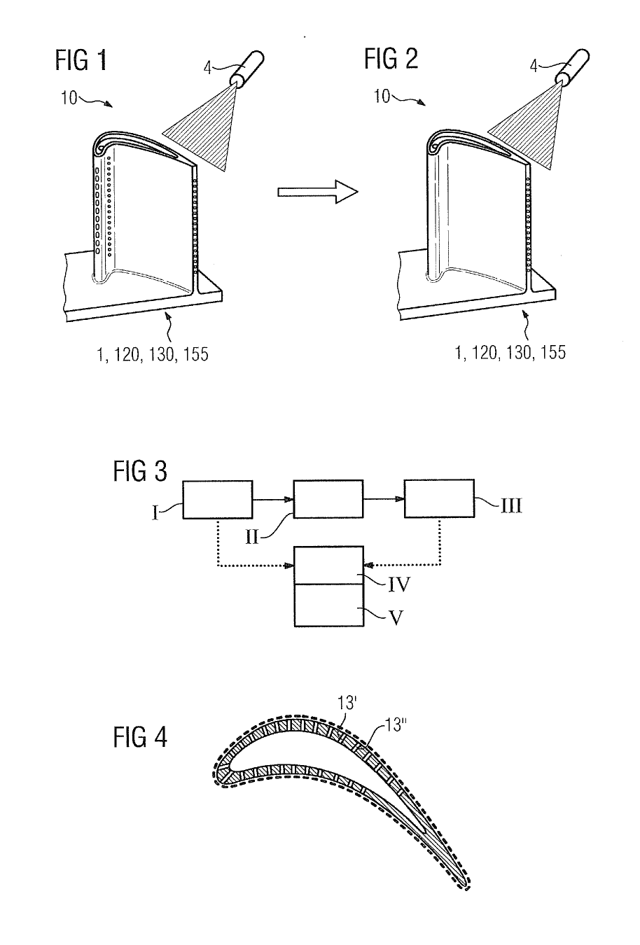

Then, the turbine blade or vane 120, 130 is coated (II in FIG. 3), and the turbine blade or vane 120, 130 is measured again by means of laser triangulation (FIG. 2 and III in FIG. 3).

The measurement by means of laser triangulation can preferably also be effected during the coating (II).

The data obtained therefrom before and after or during the coating can be compared with one another by means of a computer (IV in FIG. 3), and therefore the layer thickness can be determined at each desired position (FIG. 4) and can preferably be compared with setpoint values.

By establishing the difference between the geometrical data, the layer thickness is determined at each desired position 13′, 13″ (FIG. 4) (V in FIG. 3).

The layer thickness can be produced for metallic and ceramic layers and can be determined by means of APS, VPS, PVP, CVD.

The measurements are preferably carried out before and afterward in the same mount, preferably without the fitting and removal of the component 120, 130.

It is preferable for the measurement to be carried out only before and after the coating, because this makes the technical setup somewhat easier.

It is preferable for the component to be scanned over a large area, in the case of a turbine blade or vane 120, 130 the turbine main blade or vane part and the blade or vane platform, since different layer thicknesses are set particularly in the case of curved surfaces.

By selecting a reference point on the component 1, 120, 130, 155 (particularly in the case of a blade or vane 120, 130 this is preferably a point at the location which does not distort, e.g. on the blade or vane root—since it is very solid—or on the mount), the distortion of the component 1, 120, 130, 155, in particular of the much thinner part of the component, specifically of the main blade or vane part, which is formed by the coating process (heat) can be taken into consideration, and the actual layer thickness can be determined.

This process has a high degree of automation and can be used during the process qualification or as a process-accompanying measurement or as quality control.

Coating means application of material in quite general terms: locally, like a main blade or vane part of a turbine blade or vane, local coating on the main blade or vane part or complete coating, but also deposition welding processes.

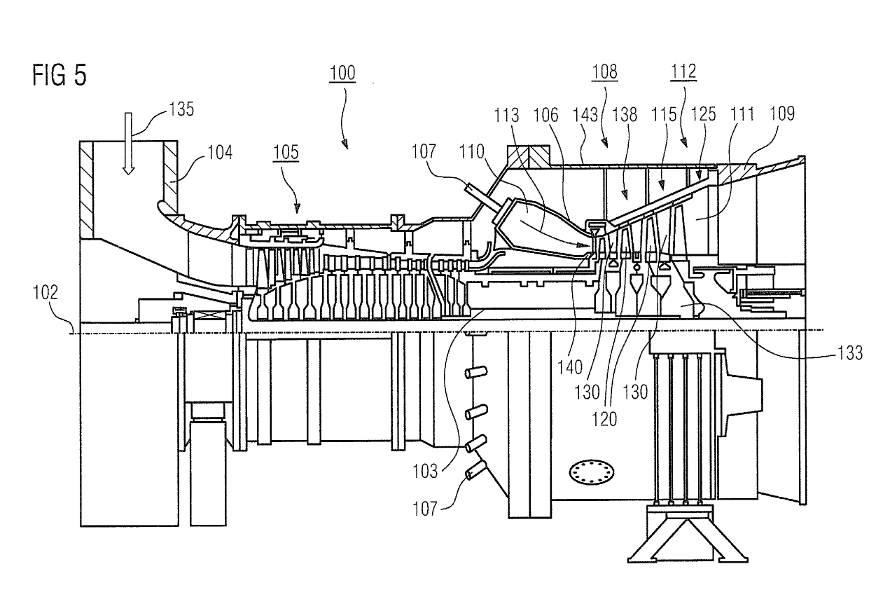

FIG. 5 shows, by way of example, a partial longitudinal section through a gas turbine 100.

In the interior, the gas turbine 100 has a rotor 103 with a shaft which is mounted such that it can rotate about an axis of rotation 102 and is also referred to as the turbine rotor.

An intake housing 104, a compressor 105, a, for example, toroidal combustion chamber 110, in particular an annular combustion chamber, with a plurality of coaxially arranged burners 107, a turbine 108 and the exhaust-gas housing 109 follow one another along the rotor 103.

The annular combustion chamber 110 is in communication with a, for example, annular hot-gas passage 111, where, by way of example, four successive turbine stages 112 form the turbine 108.

Each turbine stage 112 is formed, for example, from two blade or vane rings. As seen in the direction of flow of a working medium 113, in the hot-gas passage 111 a row of guide vanes 115 is followed by a row 125 formed from rotor blades 120.

The guide vanes 130 are secured to an inner housing 138 of a stator 143, whereas the rotor blades 120 of a row 125 are fitted to the rotor 103 for example by means of a turbine disk 133.

A generator (not shown) is coupled to the rotor 103.

While the gas turbine 100 is operating, the compressor 105 sucks in air 135 through the intake housing 104 and compresses it. The compressed air provided at the turbine-side end of the compressor 105 is passed to the burners 107, where it is mixed with a fuel. The mix is then burnt in the combustion chamber 110, forming the working medium 113. From there, the working medium 113 flows along the hot-gas passage 111 past the guide vanes 130 and the rotor blades 120. The working medium 113 is expanded at the rotor blades 120, transferring its momentum, so that the rotor blades 120 drive the rotor 103 and the latter in turn drives the generator coupled to it.

While the gas turbine 100 is operating, the components which are exposed to the hot working medium 113 are subject to thermal stresses. The guide vanes 130 and rotor blades 120 of the first turbine stage 112, as seen in the direction of flow of the working medium 113, together with the heat shield elements which line the annular combustion chamber 110, are subject to the highest thermal stresses.

To be able to withstand the temperatures which prevail there, they may be cooled by means of a coolant.

Substrates of the components may likewise have a directional structure, i.e. they are in single-crystal faun (SX structure) or have only longitudinally oriented grains (DS structure).

By way of example, iron-based, nickel-based or cobalt-based superalloys are used as material for the components, in particular for the turbine blade or vane 120, 130 and components of the combustion chamber 110.

Superalloys of this type are known, for example, from EP 1 204 776 B1, EP 1 306 454, EP 1 319 729 A1, WO 99/67435 or WO 00/44949.

The guide vane 130 has a guide vane root (not shown here), which faces the inner housing 138 of the turbine 108, and a guide vane head which is at the opposite end from the guide vane root. The guide vane head faces the rotor 103 and is fixed to a securing ring 140 of the stator 143.

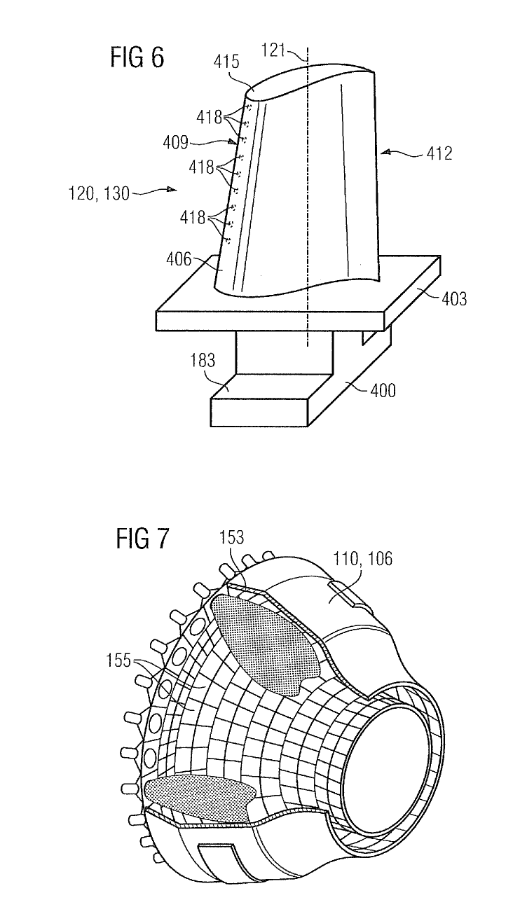

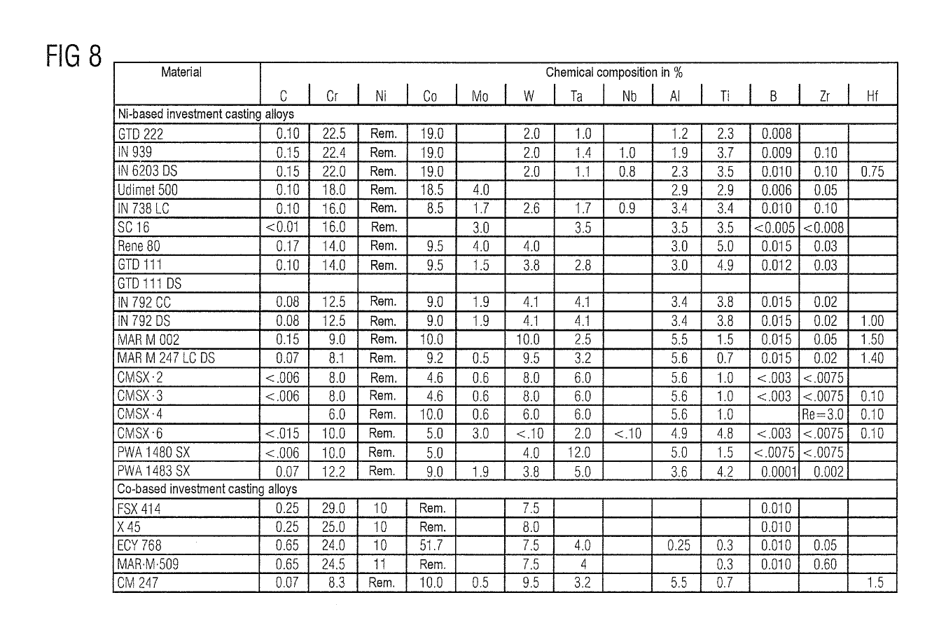

FIG. 6 shows a perspective view of a rotor blade 120 or guide vane 130 of a turbomachine, which extends along a longitudinal axis 121.

The turbomachine may be a gas turbine of an aircraft or of a power plant for generating electricity, a steam turbine or a compressor.

The blade or vane 120, 130 has, in succession along the longitudinal axis 121, a securing region 400, an adjoining blade or vane platform 403 and a main blade or vane part 406 and a blade or vane tip 415.

As a guide vane 130, the vane 130 may have a further platform (not shown) at its vane tip 415.

A blade or vane root 183, which is used to secure the rotor blades 120, 130 to a shaft or a disk (not shown), is formed in the securing region 400.

The blade or vane root 183 is designed, for example, in hammerhead form. Other configurations, such as a fir-tree or dovetail root, are possible.

The blade or vane 120, 130 has a leading edge 409 and a trailing edge 412 for a medium which flows past the main blade or vane part 406.

In the case of conventional blades or vanes 120, 130, by way of example solid metallic materials, in particular superalloys, are used in all regions 400, 403, 406 of the blade or vane 120, 130.

Superalloys of this type are known, for example, from EP 1 204 776 B1, EP 1 306 454, EP 1 319 729 A1, WO 99/67435 or WO 00/44949.

The blade or vane 120, 130 may in this case be produced by a casting process, by means of directional solidification, by a forging process, by a milling process or combinations thereof.

Workpieces with a single-crystal structure or structures are used as components for machines which, in operation, are exposed to high mechanical, thermal and/or chemical stresses.

Single-crystal workpieces of this type are produced, for example, by directional solidification from the melt. This involves casting processes in which the liquid metallic alloy solidifies to form the single-crystal structure, i.e. the single-crystal workpiece, or solidifies directionally.

In this case, dendritic crystals are oriented along the direction of heat flow and form either a columnar crystalline grain structure (i.e. grains which run over the entire length of the workpiece and are referred to here, in accordance with the language customarily used, as directionally solidified) or a single-crystal structure, i.e. the entire workpiece consists of one single crystal. In these processes, a transition to globular (polycrystalline) solidification needs to be avoided, since non-directional growth inevitably forms transverse and longitudinal grain boundaries, which negate the favorable properties of the directionally solidified or single-crystal component.

Where the text refers in general terms to directionally solidified microstructures, this is to be understood as meaning both single crystals, which do not have any grain boundaries or at most have small-angle grain boundaries, and columnar crystal structures, which do have grain boundaries running in the longitudinal direction but do not have any transverse grain boundaries. This second foiin of crystalline structures is also described as directionally solidified microstructures (directionally solidified structures).

Processes of this type are known from U.S. Pat. No. 6,024,792 and EP 0 892 090 A1; these documents form part of the disclosure with respect to the solidification process.

The blades or vanes 120, 130 may likewise have coatings protecting against corrosion or oxidation e.g. (MCrAlX; M is at least one element selected from the group consisting of iron (Fe), cobalt (Co), nickel (Ni), X is an active element and stands for yttrium (Y) and/or silicon and/or at least one rare earth element, or hafnium (HO). Alloys of this type are known from EP 0 486 489 B1, EP 0 786 017 B1, EP 0 412 397 B1 or EP 1 306 454 A1.

The density is preferably 95% of the theoretical density.

A protective aluminum oxide layer (TGO=thermally grown oxide layer) is formed on the MCrAlX layer (as an intermediate layer or as the outermost layer).

The layer preferably has a composition Co-30Ni-28Cr-8Al-0.6Y-0.7Si or Co-28Ni-24Cr-10Al-0.6Y. In addition to these cobalt-based protective coatings, it is also preferable to use nickel-based protective layers, such as Ni-10Cr-12Al-0.6Y-3Re or Ni-12Co-21Cr-11Al-0.4Y-2Re or Ni-25Co-17Cr-10Al-0.4Y-1.5Re.

It is also possible for a thermal barrier coating, which is preferably the outermost layer, to be present on the MCrAlX, consisting for example of ZrO₂, Y₂O₃-ZrO₂, i.e. unstabilized, partially stabilized or fully stabilized by yttrium oxide and/or calcium oxide and/or magnesium oxide.

The thermal barrier coating covers the entire MCrAIX layer. Columnar grains are produced in the thermal barrier coating by suitable coating processes, such as for example electron beam physical vapor deposition (EB-PVD).

Other coating processes are possible, e.g. atmospheric plasma spraying (APS), LPPS, VPS or CVD. The thermal barrier coating may include grains that are porous or have micro-cracks or macro-cracks, in order to improve the resistance to thermal shocks. The thermal barrier coating is therefore preferably more porous than the MCrAlX layer.

The blade or vane 120, 130 may be hollow or solid in form. If the blade or vane 120, 130 is to be cooled, it is hollow and may also have film-cooling holes 418 (indicated by dashed lines).

FIG. 7 shows a combustion chamber 110 of the gas turbine 100.

The combustion chamber 110 is configured, for example, as what is known as an annular combustion chamber, in which a multiplicity of burners 107, which generate flames 156, arranged circumferentially around an axis of rotation 102 open out into a common combustion chamber space 154. For this purpose, the combustion chamber 110 overall is of annular configuration positioned around the axis of rotation 102.

To achieve a relatively high efficiency, the combustion chamber 110 is designed for a relatively high temperature of the working medium M of approximately 1000° C. to 1600° C. To allow a relatively long service life even with these operating parameters, which are unfavorable for the materials, the combustion chamber wall 153 is provided, on its side which faces the working medium M, with an inner lining farmed from heat shield elements 155.

Moreover, a cooling system may be provided for the heat shield elements 155 and/or their holding elements, on account of the high temperatures in the interior of the combustion chamber 110. The heat shield elements 155 are then, for example, hollow and may also have cooling holes (not shown) opening out into the combustion chamber space 154.

On the working medium side, each heat shield element 155 made from an alloy is equipped with a particularly heat-resistant protective layer (MCrAlX layer and/or ceramic coating) or is made from material that is able to withstand high temperatures (solid ceramic bricks).

These protective layers may be similar to the turbine blades or vanes, i.e. for example MCrAlX: M is at least one element selected from the group consisting of iron (Fe), cobalt (Co), nickel (Ni), X is an active element and stands for yttrium (Y) and/or silicon and/or at least one rare earth element or hafnium (Hf). Alloys of this type are known from EP 0 486 489 B1, EP 0 786 017 B1, EP 0 412 397 B1 or EP 1 306 454 A1.

It is also possible for a, for example ceramic, thermal barrier coating to be present on the MCrAlX, consisting for example of ZrO₂, Y₂O₃-ZrO₂, i.e. unstabilized, partially stabilized or fully stabilized by yttrium oxide and/or calcium oxide and/or magnesium oxide.

Columnar grains are produced in the thermal barrier coating by suitable coating processes, such as for example electron beam physical vapor deposition (EB-PVD).

Other coating processes are possible, e.g. atmospheric plasma spraying (APS), LPPS, VPS or CVD. The thermal barrier coating may include grains that are porous or have micro-cracks or macro-cracks, in order to improve the resistance to thermal shocks.

Refurbishment means that after they have been used, protective layers may have to be removed from turbine blades or vanes 120, 130 or heat shield elements 155 (e.g. by sand-blasting). Then, the corrosion and/or oxidation layers and products are removed. If appropriate, cracks in the turbine blade or vane 120, 130 or in the heat shield element 155 are also repaired. This is followed by recoating of the turbine blades or vanes 120, 130 or heat shield elements 155, after which the turbine blades or vanes 120, 130 or the heat shield elements 155 can be reused.

1-9. (canceled)

10. A method for determining the layer thickness of a component to be coated, comprising:
measuring the layer thickness of the component at a position by means of laser triangulation;
coating the component;
measuring again the layer thickness of the component by means of laser triangulation; and
calculating a layer thickness from the various measurements of the component,
wherein the distortion of the component is taken into account, and
wherein a reference point on the component is used in order to determine the distortion of the blade or vane.

11. The method as claimed in claim 10,
wherein the layer thickness measurement is carried out only locally.

12. The method as claimed inc claim 11, wherein the layer thickness measurement is carried out only at certain points.

13. The method as claimed in claim 10, wherein the laser triangulation measurement is carried out after the coating of the component.

14. The method as claimed in claim 10, wherein the laser triangulation measurement is carried out during the coating of the component.

15. The method as claimed in claim 10, wherein the layer thickness measurement is carried out at a plurality of positions.

16. The method as claimed in claim 10, wherein the layer thickness measurement is carried out over a large area.

17. The method as claimed in claim 10, wherein the layer thickness measurement is carried out only before and only after the coating.

18. A device, comprising:
a component;
a mount for the component, wherein the mount or the component includes a reference point for determining the distortion of the component;
a sensor for laser triangulation measurement; and
a computation unit which acquires various measurements of the component before, during or after the coating and which makes it possible to establish the difference between the measurements as a result of which a layer thickness is determined.

19. The device as claimed in claim 19, wherein the device is used to carry out the method as claimed in claim 10.
